(19) United States
(12) Patent Application Publication
(10) Pub. No.: US 2017/0278732 A1
(43) Pub. Date: Sep. 28, 2017

(54) WAFER PLACEMENT APPARATUS

(71) Applicant: NGK INSULATORS, LTD., Nagoya-City (JP)

(72) Inventor: Shingo AMANO, San Jose, CA (US)

(73) Assignee: NGK INSULATORS, LTD., Nagoya-City (JP)

(21) Appl. No.: 15/468,658

(22) Filed: Mar. 24, 2017

(30) Foreign Application Priority Data
Mar. 28, 2016 (JP) 2016-063623

(51) Int. Cl. H01L 21/67; H01L 21/683; H05B 1/02; H01L 21/687

(52) U.S. Cl. CPC H01L 21/67103; H01L 21/68792; H01L 21/68757; H01L 21/6831; H05B 1/0233

(57) ABSTRACT

A wafer placement apparatus 30 includes a ceramic substrate 32 having a wafer placement surface, a heater electrode 34 embedded in the ceramic substrate 32, and feeder rods 36 and 37 made of Cu and electrically connected to the heater electrode 34 through a surface of the ceramic substrate 32 opposite the wafer placement surface. When one end and the other end of the feeder rod 36 in an unengaged state are a fixed end and a free end, respectively, and when a relationship between a stress applied to the feeder rod 36 at a position 50 mm apart from the fixed end toward the free end and a strain at the position is obtained, the stress is in a range of 5 to 10 N when the strain is 1 mm.

### BACKGROUND OF THE INVENTION

1. Field of the invention

The present invention relates to a wafer placement apparatus.

2. Description of the Related Art

An example of a wafer placement apparatus is disclosed in, for example, PTL 1. As illustrated in FIG. 4, this wafer placement apparatus includes a ceramic substrate 102, a heater electrode 104 embedded in the ceramic substrate 102, and a feeder rod 108 made of Ni. The feeder rod 108 is electrically connected to an embedded terminal 106 of the heater electrode 104 through a surface of the ceramic substrate 102 opposite a wafer placement surface of the ceramic substrate 102. A stress reducing layer 110 is provided between the embedded terminal 106 of the heater electrode 104 and the feeder rod 108. The stress reducing layer 110 is joined to the embedded terminal 106 of the heater electrode 104 by a solder joining layer 112, and to the feeder rod 108 by a solder joining layer 114.

### CITATION LIST

### Patent Literature

[PTL 1] Japanese Patent No. 5029257

### SUMMARY OF THE INVENTION

Unfortunately, since the feeder rod 108 of the above-described wafer placement apparatus is made of Ni, a magnetic field is generated around the feeder rod 108 when a current is supplied to the heater electrode 104. Therefore, there is a risk that a semiconductor manufacturing process will be adversely affected.

The present invention has been made to solve this problem, and its object is to suppress the generation of a magnetic field around the feeder rod.

A wafer placement apparatus of the poresent invention comprises:

a ceramic substrate having a wafer placement surface;

at least one electrode embedded in the ceramic substrate, the electrode being an electrostatic electrode, a heater electrode, or a high-frequency electrode; and

a feeder rod that is made of Cu and electrically connected to the electrode through a surface of the ceramic substrate opposite the wafer placement surface.

According to this wafer placement apparatus, the electric power is supplied to the electrode through the feeder rod made of Cu, which is not a magnetic material. Therefore, the generation of the magnetic field around the feeder rod can be suppressed. Accordingly, the risk that the result of treatment will differ only in the region of the wafer around the feeder rod in a semiconductor manufacturing process can be reduced.

In the wafer placement apparatus according to the present invention, when one end and the other end of the feeder rod are a fixed end and a free end, respectively, and when a relationship between a stress applied to the feeder rod at a position 50 mm apart from the fixed end toward the free end and a strain at the position is obtained, the stress is preferably in a range of 5 to 10 N when the strain is 1 mm. One end of the feeder rod is connected to the electrode, and the other end of the feeder rod is connected to a fixing device. A load is applied to the feeder rod when the other end of the feeder rod is fixed to the fixing device. Since the stress applied to the feeder rod and the strain of the feeder rod have the above-described relationship, the load can be absorbed by the feeder rod. Therefore, the connecting portion between the feeder rod and the electrode does not receive a large load. The above-described relationship between the stress and strain can be obtained by, for example, annealing the feeder rod.

The wafer placement apparatus according to the present invention may further include a connecting terminal that is joined to the electrode by a Au—Ni solder joining layer or joined to one surface of a heat-resistant stress reducing layer by a Au—Ni solder joining layer, another surface of the heat-resistant stress reducing layer being joined to the electrode. The ceramic substrate may be made of AlN, and the electrode and the connecting terminal may be made of Mo or a Mo alloy. The feeder rod may be fastened to the connecting terminal. The heat-resistant stress reducing layer is a stress reducing layer having a heat-resistant temperature of 1000° C. or more. In this case, since every component has a high heat-resistant temperature, the wafer placement apparatus according to the present invention can be used even when the semiconductor manufacturing process is performed at a high temperature. Even when a magnetic field is generated around the connecting terminal made of Mo or a Mo alloy, the influence of the magnetic field is small since the connecting terminal is shorter than the feeder rod.

The connecting terminal can be omitted if the electrode or the stress reducing layer is directly joined to the feeder rod with a Au—Ni solder joining layer. The Au—Ni solder joining layer is formed by treating a Au—Ni solder material at a high joining temperature (about 1000° C.). At this time, Cu and Au come into contact with each other at the boundary between the feeder rod made of Cu and the Au—Ni solder material. Since the Au/Cu mixed layer has a low melting point, there is a risk that the feeder rod will melt at the joining temperature of the Au—Ni solder material. Therefore, a connecting terminal made of a material that does not have such a risk is used. If a solder material that does not contain Au is used, the feeder rod made of Cu may be joined to the electrode or the stress reducing layer. However, such a solder material generally has a low joining temperature, and there is a risk that the solder material will melt when the wafer placement apparatus is used at a high temperature. Accordingly, the Au—Ni solder material, which does not have such a risk, is used.

In the wafer placement apparatus including connecting terminal according to the present invention, one of the feeder rod and the connecting terminal may include an external thread, and the other of the feeder rod and the connecting terminal may include an internal thread. The feeder rod and the connecting terminal may be fastened to each other by screwing the external thread and internal thread together. In this case, the feeder rod and the connecting terminal can be easily attached to and separated from each other.

### BRIEF DESCRIPTION OF THE DRAWINGS

FIG. 1 illustrates the structure of a plasma treatment apparatus 10 according to an embodiment.

FIG. 2 is an enlarged partial view of FIG. 1.

FIG. 3 is a graph showing the relationship between the stress applied to a feeder rod made of Cu and strain.

FIG. 4 illustrates the structure of a wafer placement apparatus according to the related art.

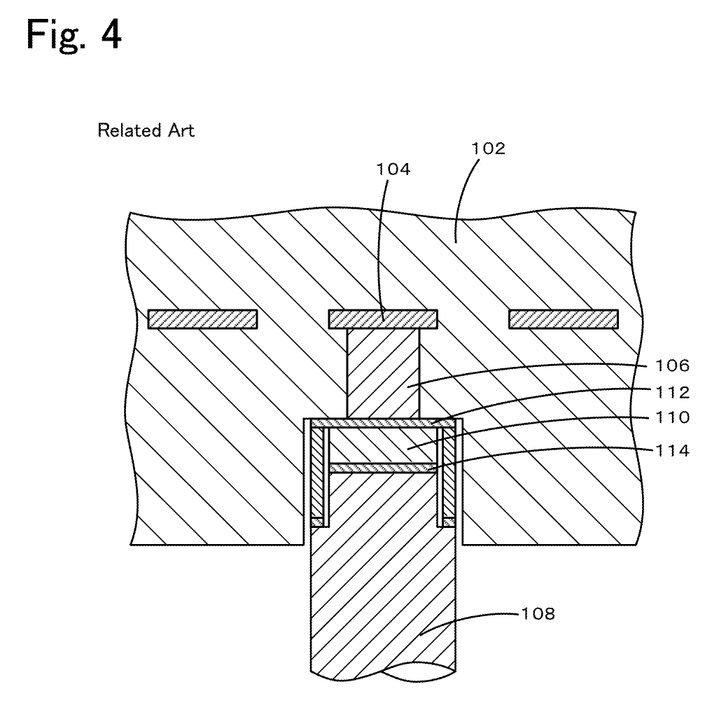

### DETAILED DESCRIPTION OF THE INVENTION

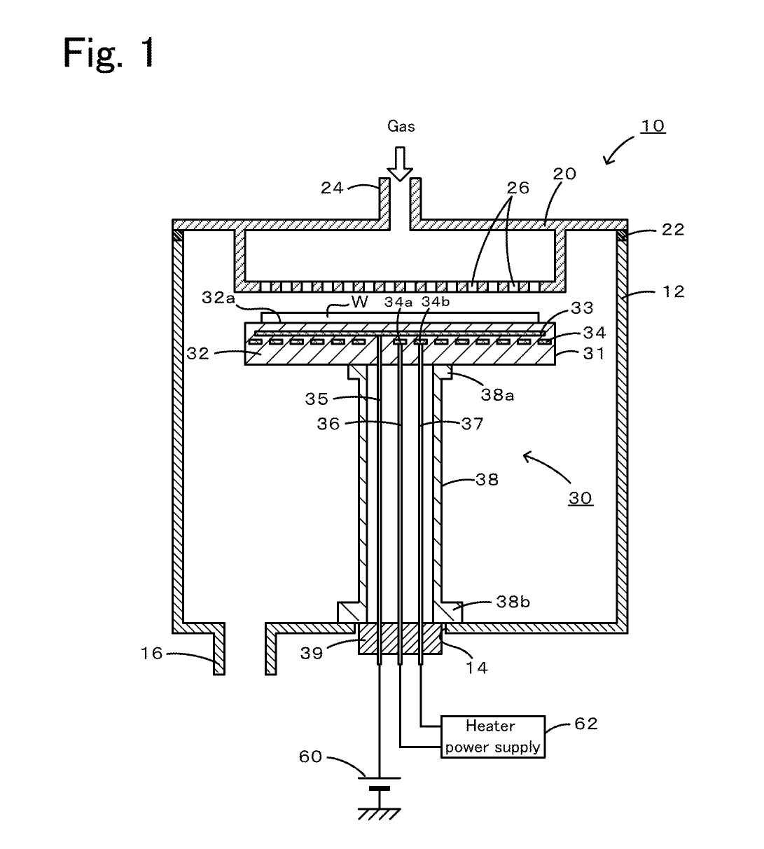

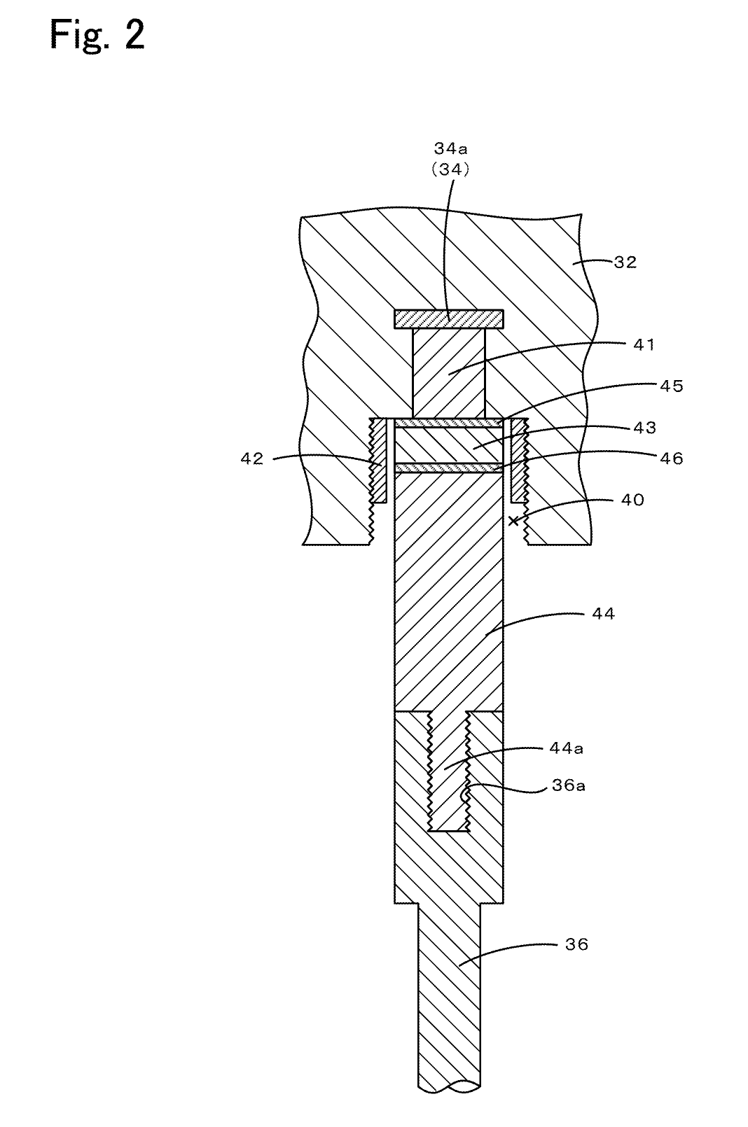

A preferred embodiment of the present invention will be described with reference to the drawings. FIG. 1 illustrates the structure of a plasma treatment apparatus 10, and FIG. 2 is an enlarged partial view of FIG. 1.

As illustrated in FIG. 1, the plasma treatment apparatus 10 includes a treatment vessel 12, a shower head 20, and a wafer placement apparatus 30.

The treatment vessel 12 is a box-shaped vessel made of an aluminum alloy or the like. The treatment vessel 12 has a circular hole 14 at substantially the center of the bottom surface thereof. The treatment vessel 12 also has an exhaust pipe 16 at the bottom. The exhaust pipe 16 is provided with a pressure regulating valve and a vacuum pump (not shown) at intermediate positions thereof, and is capable of adjusting the pressure in the treatment vessel 12 to a desired pressure. The treatment vessel 12 is open at the top.

The shower head 20 is attached to the treatment vessel 12 so as to block the opening at the top of the treatment vessel 12. An insulating member 22 is disposed between the opening edge at the top of the treatment vessel 12 and the shower head 20. The treatment vessel 12, whose opening is blocked by the shower head 20, is configured so that the inside thereof is maintained airtight. The shower head 20 ejects gas introduced through a gas introduction pipe 24 toward a wafer W placed on a wafer table 31 through multiple gas ejection holes 26. In the present embodiment, the shower head 20 is connected to a high-frequency power supply for generating plasma (not shown). Thus, the shower head 20 functions as an electrode for generating plasma.

The wafer placement apparatus 30 includes the wafer table 31 and a hollow shaft 38.

The wafer table 31 is a disc-shaped ceramic substrate 32 in which an electrostatic electrode 33 and a heater electrode 34 are embedded. In the present embodiment, the ceramic substrate 32 is made of an AlN ceramic. One surface of the ceramic substrate 32 serves as a wafer placement surface 32a on which the wafer W is placed.

The electrostatic electrode 33 is made of Mo, and is embedded between the wafer placement surface 32a and the heater electrode 34. The electrostatic electrode 33 is connected to a direct-current power supply 60 for electrostatic chucking by a feeder rod 35. The feeder rod 35 is inserted through a surface (back surface) of the ceramic substrate 32 opposite the wafer placement surface 32a. When electric power is supplied to the electrostatic electrode 33 from the direct-current power supply 60, the wafer W is attracted to and held by the wafer placement surface 32a due to electrostatic force. The electrostatic electrode 33 also serves as an electrode for generating plasma (electrode paired with the shower head 20).

The heater electrode 34 is also made of Mo, and continuously extends from a first end 34a to a second end 34b over the entire area of the disc-shaped ceramic substrate 32. Feeder rods 36 and 37 are respectively connected to the first end 34a and the second end 34b of the heater electrode 34. A heater power supply 62 is connected between the two feeder rods 36 and 37. The heater electrode 34 heats the wafer W that is attracted to and held by the wafer placement surface 32a when electric power is supplied thereto from the heater power supply 62.

The hollow shaft 38 is made of a ceramic, and flanges 38a and 38b are provided around the openings at both ends of the hollow shaft 38. The flange 38a at one end of the hollow shaft 38 is airtightly joined to the back surface of the ceramic substrate 32 by solid-state welding. The flange 38b at the other end of the hollow shaft 38 is airtightly joined to the periphery of the circular hole 14 formed in the bottom surface of the treatment vessel 12. Therefore, the inside of the hollow shaft 38 is completely isolated from the inside of the treatment vessel 12. A rod-fixing device 39 is attached to the back surface of the flange 38b of the hollow shaft 38. The rod-fixing device 39 secures the feeder rods 35, 36, and 37, which extend therethrough, with a clamp mechanism (not shown).

A structure for connecting the feeder rod 35 to the electrostatic electrode 33 and a structure for connecting the feeder rods 36 and 37 to the heater electrode 34 will now be described. Since these connecting structures are the same, only the structure for connecting the feeder rod 36 to the first end 34a of the heater electrode 34 will be described with reference to FIG. 2.

A recess 40 is formed in the back surface of the ceramic substrate 32 so as to be recessed toward the first end 34a of the heater electrode 34. The inner peripheral surface of the recess 40 is threaded. An end surface of an embedded terminal 41, which is connected to the first end 34a of the heater electrode 34, is exposed at the bottom surface of the recess 40. The embedded terminal 41 is made of the same material as the heater electrode 34, that is, Mo in this example. A metal cylindrical ring 42 having a threaded outer peripheral surface is screwed into the recess 40. The cylindrical ring 42 reinforces the inner peripheral surface of the recess 40, and is made of Ni in the present embodiment. A stress reducing layer 43 and a connecting terminal 44 are arranged in this order on the bottom surface of the recess 40 in the cylindrical ring 42. The stress reducing layer 43 reduces a stress generated between the embedded terminal 41 and the connecting terminal 44, more specifically, a stress generated due to a difference in thermal expansion between the embedded terminal 41 and the connecting terminal 44. In the present embodiment, the stress reducing layer 43 is made of Kovar (Fe—Ni—Co alloy), and the connecting terminal 44 is made of Mo. The embedded terminal 41 and the stress reducing layer 43 are joined together by a solder joining layer 45. The stress reducing layer 43 and the connecting terminal 44 are joined together by a solder joining layer 46. The solder joining layers 45 and 46 are made of a Au—Ni solder material in consideration of heat resistance. The upper limit of the operating temperature of the wafer placement apparatus 30 according to the present embodiment is 700° C. Since the joining temperature of Au and Ni is about 1000° C., the solder joining layers 45 and 46 are resistant to the upper limit of the operating temperature. The connecting terminal 44 includes an external thread 44a on an end surface opposite the end surface joined to the stress reducing layer 43. The external thread 44a is screwed into an internal thread 36a provided at an end of the feeder rod 36, which is made of Cu. When one end and the other end (end near the internal thread 36a) of the feeder rod 36 in an unengaged state are a fixed end and a free end, respectively, and when the relationship between the stress applied to the feeder rod at a position 50 mm apart from the fixed end toward the free end and the strain (displacement) at this position is obtained, the stress is in the range of 5 to 10 N when the strain is 1 mm.

The process of connecting the feeder rod 36 to the first end 34a of the heater electrode 34 will now be described. First, a Au—Ni solder material, the stress reducing layer 43, a Au—Ni solder material, and the connecting terminal 44 are disposed, in this order, on the end surface of the embedded terminal 41 exposed at the bottom surface of the recess 40. In this state, the temperature is increased to the bonding temperature of Au and Ni (about 1000° C.), and then reduced. As a result, the embedded terminal 41 and the stress reducing layer 43 are joined together by the solder joining layer 45, and the stress reducing layer 43 and the connecting terminal 44 are joined together by the solder joining layer 46. In FIG. 2, a gap is provided between the inner peripheral surface of the cylindrical ring 42 and the stress reducing layer 43. However, in practice, the Au—Ni solder material in a molten state flows into the gap and is then solidified so that a solder joining layer is formed. Since the bonding temperature is as high as about 1000° C., the connecting terminal 44 is made of a material resistant to such a high temperature (Mo in the present embodiment).

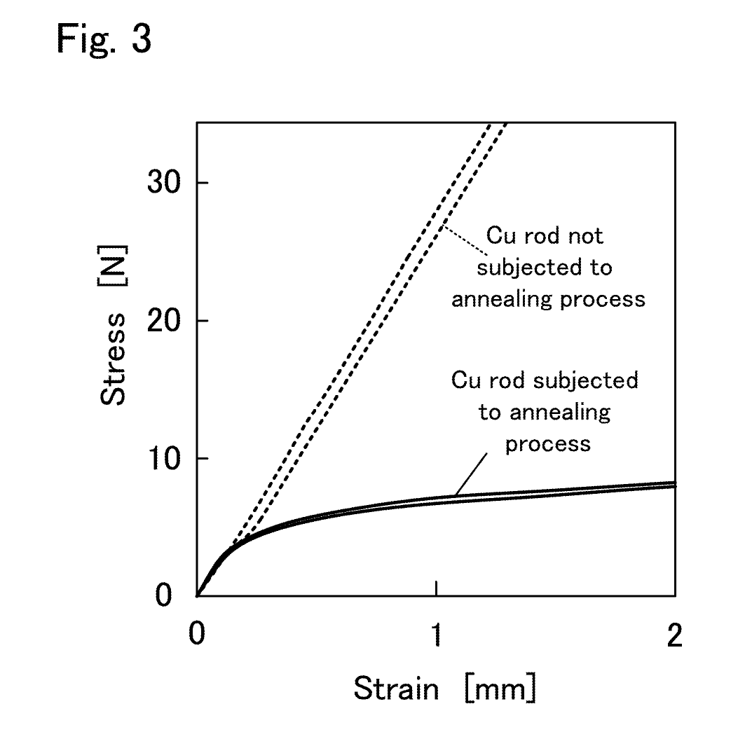

Next, the feeder rod 36 is subjected to an annealing process, and then the internal thread 36a of the feeder rod 36 is screwed onto the external thread 44a of the connecting terminal 44. FIG. 3 is a graph showing the relationship between the stress applied to a feeder rod, which is made of Cu and has a diameter of 4 mm, at a position 50 mm apart from one end, which is a fixed end, toward the other end, which is a free end, and the strain at this position. The graph shows both the result obtained when the annealing process was performed and the result obtained when the annealing process was not performed. The measurement was performed twice for each case. The annealing process was performed in a vacuum atmosphere by maintaining the temperature at a maximum temperature of 500° C. for one hour. As is clear from FIG. 3, when the strain is 1 mm, the stress is 25 to 30 N for the feeder rod that was not subjected to the annealing process, but is 5 to 10 N (more specifically, 6 to 8 N) for the feeder rod that was subjected to the annealing process. This shows that the feeder rod that was subjected to the annealing process was more flexible than the feeder rod that was not subjected to the annealing process. The internal thread 36a of the feeder rod 36 subjected to the annealing process is screwed onto the external thread 44a of the connecting terminal 44.

The feeder rod 36 integrated with the connecting terminal 44 is secured by a clamp mechanism mounted in the rod-fixing device 39 illustrated in FIG. 1. When the feeder rod 36 is not subjected to the annealing process and is too hard, the load applied to the feeder rod 36 when the feeder rod 36 is assembled to the rod-fixing device 39 directly affects the joining portions (solder joining layers), and therefore, there is a risk of separation. In contrast, when the feeder rod 36 is subjected to the annealing process and is soft, even when the load is applied to the feeder rod 36 when the feeder rod 36 is assembled to the rod-fixing device 39, the load is absorbed due to the flexibility of the feeder rod 36. Therefore, the joining portions (solder joining layers) do not receive a large load and there is no risk of separation.

The connecting terminal 44 can be omitted if the stress reducing layer 43 is directly joined to a feeder rod (without the internal thread) made of Cu with a solder joining layer. The solder joining layer is formed by treating a Au—Ni solder material at a high joining temperature (about 1000° C.). At this time, Cu and Au come into contact with each other at the boundary between the feeder rod 36 made of Cu and the Au—Ni solder material. Since the Au/Cu mixed layer has a low melting point, there is a risk that the feeder rod 36 will melt at the joining temperature of the Au—Ni solder material. Therefore, the connecting terminal 44, which is made of a material that does not have such a risk, is provided between the stress reducing layer 43 and the feeder rod 36. If a solder material that does not contain Au is used instead of the Au—Ni solder material, the stress reducing layer 43 may be joined to the feeder rod 36 made of Cu. However, such a solder material has a low joining temperature, and there is a risk that the solder material will melt when the wafer placement apparatus 30 is used at a temperature near the upper limit of the operating temperature. Accordingly, the Au—Ni solder material, which does not have such a risk, is used.

According to the wafer placement apparatus 30 of the present embodiment described above, the electric power is supplied to the electrostatic electrode 33 and the heater electrode 34 through the feeder rods 35 to 37 made of Cu, which is not a magnetic material. Therefore, the risk that the magnetic field will be generated is lower than that in the case where feeder rods made of Ni are used. Accordingly, the risk that the result of plasma treatment will differ only in the regions of the wafer W around the feeder rods 35 to 37 in a semiconductor manufacturing process can be reduced.

The feeder rods 35 to 37 made of Cu are structured such that, when the above-described relationship between the stress and strain is obtained, the stress is in the range of 5 to 10 N when the strain is 1 mm. Therefore, even when a load is applied to the feeder rods 35 to 37 when the free ends of the feeder rods 35 to 37 are assembled to the rod-fixing device 39, the load is absorbed due to the flexibility of the feeder rods 35 to 37. Therefore, the joining portions (solder joining layers) do not receive a large load, and there is no risk of separation.

In addition, in the wafer placement apparatus 30, the ceramic substrate 32 is made of AlN, the electrostatic electrode 33 and the heater electrode 34 are made of Mo, the stress reducing layer 43 is made of Kovar, the connecting terminal 44 is made of Mo, and the feeder rod 36 is made of Cu. The heat-resistant temperatures of these materials are higher than or equal to 1000° C. The heat-resistant temperatures of the solder joining layers 45 and 46 are similar to those of the above-described materials. Therefore, the wafer placement apparatus 30 according to the present embodiment can be used even when the semiconductor manufacturing process is performed at a high temperature.

Since the feeder rod 36 and the connecting terminal 44 are screwed onto each other, the feeder rod 36 and the connecting terminal 44 can be easily attached to and separated from each other.

The present invention is not limited to the above-described embodiment, and can be carried out by various modes as long as they belong to the technical scope of the invention.

For example, although the stress reducing layer 43 is provided in the above-described embodiment, the stress reducing layer 43 may be omitted because the embedded terminal 41 and the connecting terminal 44 are both made of Mo and the risk that the stress will be generated due to a difference in thermal expansion between them is very low. In other words, the connecting terminal 44 may be bonded to the embedded terminal 41 by the solder joining layer 45. Also in this case, an effect similar to that of the above-described embodiment can be obtained. When the stress reducing layer 43 is a magnetic body, the generation of the magnetic field can be further suppressed by omitting the stress reducing layer 43.

In the above-described embodiment, the ceramic substrate 32 is made of AlN, the electrostatic electrode 33 and the heater electrode 34 are made of Mo, the stress reducing layer 43 is made of Kovar, the connecting terminal 44 is made of Mo, and the solder joining layers 45 and 46 are made of a Au—Ni solder material. However, other materials may be used.

In the above-described embodiment, the connecting terminal 44 is made of Mo. However, the material of the connecting terminal 44 may be changed to a non-magnetic body (for example, non-magnetic stainless steel). In this case, the generation of the magnetic field can be further suppressed.

In the above-described embodiment, the heater electrode 34 is a single-zone heater electrode that continuously extends over the entire wafer placement surface having a circular shape. However, the entire wafer placement surface may be sectioned into a plurality of zones, and a heater electrode may be provided for each zone. In this case, the number of feeder rods increases in accordance with the number of heater electrodes. Each feeder rod may be connected to the corresponding heater electrode by a method similar to that in the above-described embodiment.

Although the connecting terminal 44 and the feeder rod 36 are screwed onto each other in the above-described embodiment, the connecting terminal 44 and the feeder rod 36 may instead be fastened to each other by pressure bonding, by press-fitting one of them to the other, or by crimping.

The present application claims priority of Japanese Patent Application No. 2016-063623 filed on Mar. 28, 2016, the entire contents of which are incorporated herein by reference.

What is claimed is:

1. A wafer placement apparatus comprising:
a ceramic substrate having a wafer placement surface;
at least one electrode embedded in the ceramic substrate, the electrode being an electrostatic electrode, a heater electrode, or a high-frequency electrode; and
a feeder rod that is made of Cu and electrically connected to the electrode through a surface of the ceramic substrate opposite the wafer placement surface.

2. The wafer placement apparatus according to claim 1, wherein, when one end and the other end of the feeder rod are a fixed end and a free end, respectively, and when a relationship between a stress applied to feeder rod at a position 50 mm apart from the fixed end toward the free end and a strain at the position is obtained, the stress is in a range of 5 to 10 N when the strain is 1 mm.

3. The wafer placement apparatus according to claim 1, wherein the feeder rod is annealed.

4. The wafer placement apparatus according to claim 1, further comprising:
a connecting terminal that is joined to the electrode by a Au—Ni solder joining layer or joined to one surface of a heat-resistant stress reducing layer by a Au—Ni solder joining layer, another surface of the heat-resistant stress reducing layer being joined to the electrode,
wherein the ceramic substrate is made of AlN,
the electrode and the connecting terminal are made of Mo or a Mo alloy, and
the feeder rod is fastened to the connecting terminal.

5. The wafer placement apparatus according to claim 4,
wherein one of the feeder rod and the connecting terminal includes an external thread and the other of the feeder rod and the connecting terminal includes an internal thread, and
the feeder rod and the connecting terminal are fastened to each other by screwing the external thread and internal thread together.
